(19) United States
(12) Patent Application Publication
(10) Pub. No.: US 2013/0258182 A1
(43) Pub. Date: Oct. 3, 2013

(54) WAFER LEVEL CAMERA MODULE WITH PROTECTIVE TUBE

(71) Applicants: Wei-Feng Lin, Hsinchu City (TW); Wen-Jen Ho, Qionglin (TW)

(72) Inventors: Wei-Feng Lin, Hsinchu City (TW); Wen-Jen Ho, Qionglin (TW)

(73) Assignee: OMNIVISION TECHNOLOGIES, INC., Santa Clara, CA (US)

(21) Appl. No.: 13/435,649

(22) Filed: Mar. 30, 2012

(51) Int. Cl. H04N 5/225; H05K 13/04; B23P 11/00

(52) U.S. Cl. 348/374; 29/428; 156/297; 348/E05.024

(57) ABSTRACT

An apparatus includes an image sensor module with a lens stack disposed on the image sensor module. A protective tube is disposed on the image sensor module and encloses the lens stack. A metal housing encloses the protective tube. The metal housing includes a housing foot adapted to secure the image sensor module between the housing foot of the metal housing and the protective tube.

### REFERENCE TO RELATED APPLICATION(S)

This application is related to co-pending application Ser. No. ______, filed Mar. 30, 2012, entitled “Wafer Level Camera Module With Snap-In Latch,” and assigned to the Assignee of the present application.

### BACKGROUND INFORMATION

1. Field of the Disclosure

The present invention relates generally to image sensors. More specifically, embodiments of the present invention are related to wafer level camera modules.

2. Background

A wafer level camera module is a camera module that has a small footprint and can be utilized in applications such for example mobile phones, notebook computers, tablet computers, and the like. A wafer level camera module includes optics to focus an image and an image sensor for sensing the image. In order to capture a high quality image, the optics of the camera module typically includes several lenses that are separated by glass wafers and/or spacers. The lenses are stacked in a lens stack. The lens stack is disposed on an image sensor module. The lens stack and the image sensor module are typically enclosed within a metal housing.

There are continuing efforts to reduce production costs and improve yields of the manufacturing and assembly of wafer level camera modules. A consequence of low yields is increased production costs. Accordingly, a wafer level camera module and wafer level camera module assembly method that may increase yields and thus lower production costs is desired. Furthermore, wafer level camera modules having enhanced mechanical strength, improved electromagnetic compatibility (EMC) performance, and reduced stray light related artifacts are desired.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is an illustration of a typical wafer level camera module.

FIG. 2 illustrates a lens stack, an image sensor module, a metal housing, and an interposer in a typical wafer level camera module.

FIGS. 3A-3E illustrate a process for assembling an example wafer level camera module in accordance with the teachings of the present invention.

FIG. 4 illustrates an example of a cap of a protective tube without a ledge in accordance with the teachings of the present invention.

FIG. 5 illustrates a variation of an example protective tube in accordance with the teachings of the present invention.

FIGS. 6A-6I illustrate an example of an assembly process in wafer level using the reconstruction of components in wafer level after singulation in accordance with the teachings of the present invention.

FIGS. 7A-7C illustrate various examples of cross-section shapes of example lens stacks, protective tubes and metal housings in accordance with the teachings of the present invention.

### DETAILED DESCRIPTION

As will be shown, methods and apparatuses that provide examples of a wafer level camera module with a protective tube are disclosed. In the following description, numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment”, “an embodiment”, “one example” or “an example” means that a particular feature, structure or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or subcombinations in one or more embodiments or examples. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

Example methods and apparatuses directed to a wafer level camera module with a protective tube are disclosed. As will be appreciated, a wafer level camera module and wafer level camera module assembly method according to the teachings of the present invention may provide increased yields with reduced production costs. In addition, examples of the disclosed wafer level camera modules including protective tubes provide enhanced mechanical strength, which provide extra protection to the lens stack as well as improved electromagnetic compatibility (EMC) performance, and reduced stray light related artifacts in accordance with the teachings of the present invention.

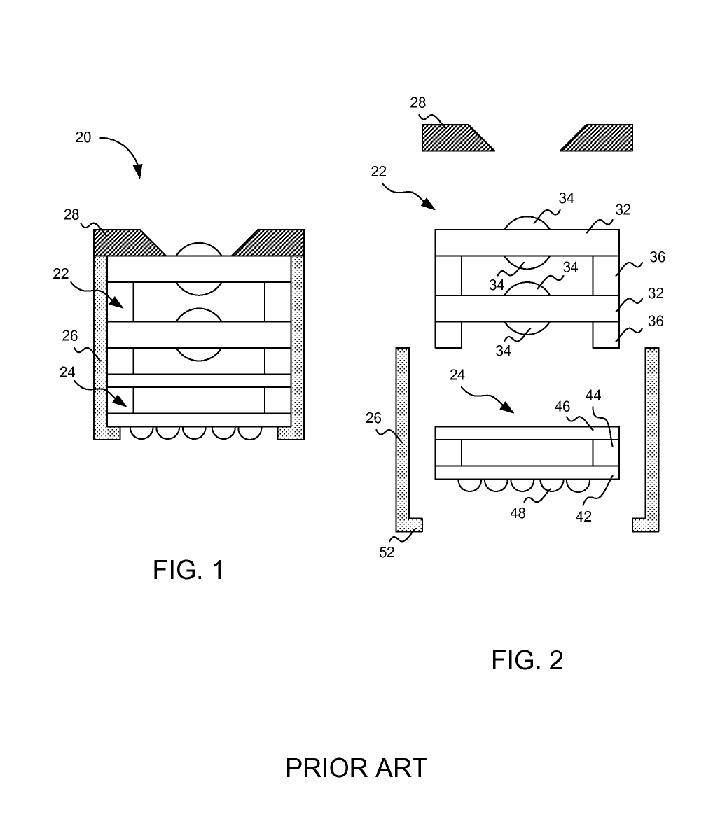

To illustrate, FIG. 1 is a schematic diagram of a typical wafer level camera module 20. Wafer level camera module 20 includes a lens stack 22 and an image sensor module 24 in a metal housing 26. An interposer 28, which is a cap with an aperture, is configured to close metal housing 26.

FIG. 2 illustrates lens stack 22, image sensor module 24, metal housing 26, and interposer 28. As shown, lens stack 22 includes one or more lenses 34 on glass wafers 32 and spacers 36. Image sensor module 24 includes an image sensor die 42, a spacer 44 mounted on the image sensor die, a cover glass 46 mounted on the spacer, and a plurality of solder balls 48 mounted to the image sensor die. Metal housing 26 may include a bent hook-like housing foot 52.

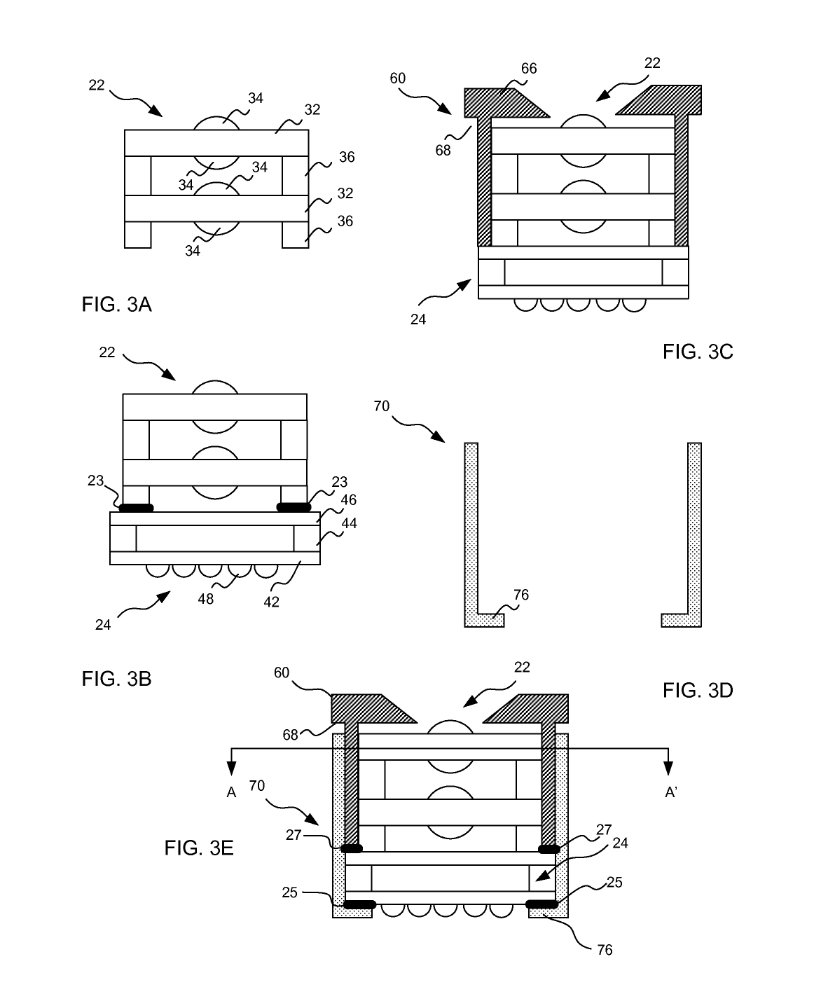

FIGS. 3A-3E illustrate a process for assembling an example wafer level camera module in accordance with the teachings of the present invention. FIG. 3A shows a lens stack 22 including one or more lenses 34 on glass wafers 32 and spacers 36. FIG. 3B shows lens stack 22 disposed on an image sensor module 24, which includes an image sensor die 42, spacers 44 mounted on the image sensor die, a cover glass 46 mounted on spacers 44, and a plurality of solder balls 48 mounted to the image sensor. In other examples, it is appreciated that plurality of solder balls 48 may be replaced with solder bumps, solder pads, or other electrical connection elements. In one example, glue or an adhesive may be applied between lens stack 22 and image sensor module 24.

In the illustrated example, FIG. 3C shows a protective tube 60 disposed on image sensor module 24 and enclosing lens stack 22. In the example, protective tube 60 includes a cap 66 with aperture as shown. In one example, cap 66 includes an extension or ledge 68. In one example, there is a gap between cap 66 and lens stack 22, as shown. In another example, there is no gap between cap 66 and lens stack 22.

In the illustrated example, FIG. 3D shows a metal housing 70, which is adapted to enclose protective tube 60. As shown in the depicted example, metal housing includes a hook-like housing foot 76. In one example, the image sensor module 24 is adapted to be secured between housing foot 76 of metal housing 70 and protective tube 60 when protective tube 60 is enclosed within metal housing 70.

To illustrate, FIG. 3E illustrates metal housing 70 enclosing protective tube 60 with protective tube 60 being inserted into metal housing 70. As shown, the inner surface of housing foot 76 presses against image sensor module 24 from one side and protective tube 60 presses image sensor module 24 from the other side. In this manner, image sensor module 24 is secured between housing foot 76 of metal housing 70 and protective tube 60 when protective tube 60 is enclosed within metal housing 70 in accordance with the teachings of the present invention.

It is appreciated that protective tube 60 enclosed in metal housing 70 as described secures as well as aligns lens stack 22 and image sensor module 24. Thus, the utilization of protective tube 60 with metal housing 70 as described increases the yields and in turn, reduces overall production costs. Protective tube 60 also enhances the mechanical strength, improves electromagnetic compatibility (EMC) performance, and prevents stray light related artifacts in accordance with the teachings of the present invention.

In one example, glue or a first adhesive 23 may be applied between lens stack 22 and image sensor module 24, as shown in FIG. 3B. In addition, a second adhesive 25 may be applied between the inner surface of housing foot 76 and image sensor module 24, and a third adhesive 27 may be applied between protective tube 60 and image sensor module 24, as shown in the example depicted in FIG. 3E.

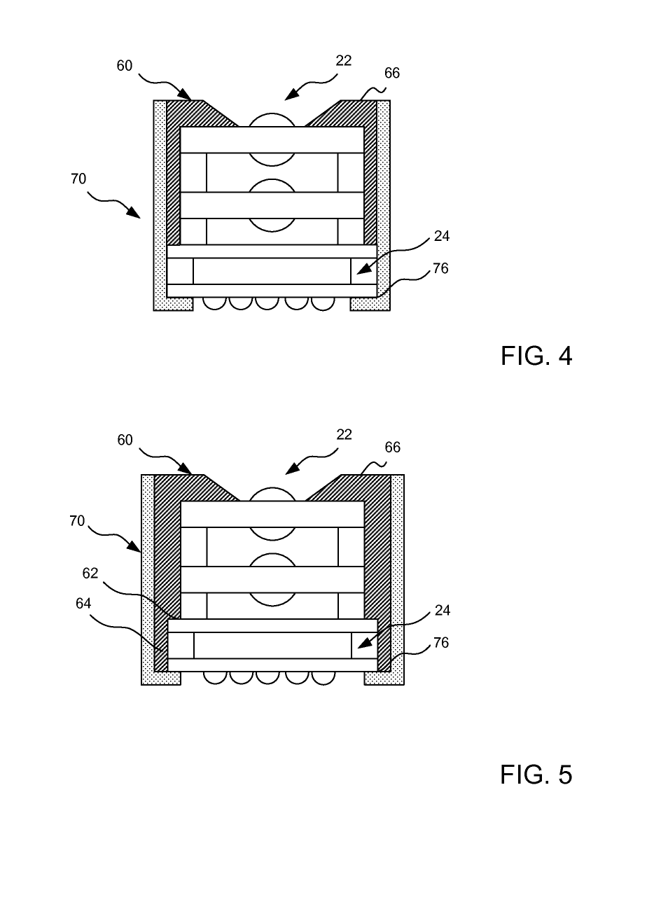

FIG. 4 illustrates another example wafer level camera module in accordance with the teachings of the present invention. It is noted that the example wafer level camera module illustrated in FIG. 4 shares many similarities with the example wafer level camera module illustrated in FIGS. 3A-3E. However, a difference is that the example wafer level camera module illustrated in FIG. 4 shows cap 66 of protective tube 60 without a ledge 68, as illustrated in the example wafer level camera module shown in FIGS. 3A-3E.

FIG. 5 illustrates a variation of an example protective tube 60 in accordance with the teachings of the present invention. In particular, FIG. 5 shows protective tube 60 including a recess defined by a stop 62 and a thinned wall 64 adapted to accept and hold image sensor module 24. It is appreciated that other variations of protective tube 60 are also possible in accordance with the teachings of the present invention. It is noted that the examples illustrated in FIGS. 4-5 show that there is no gap between cap 66 and lens stack 22. In other examples, it is noted that there may be a gap between cap 66 and lens stack 22 (not shown).

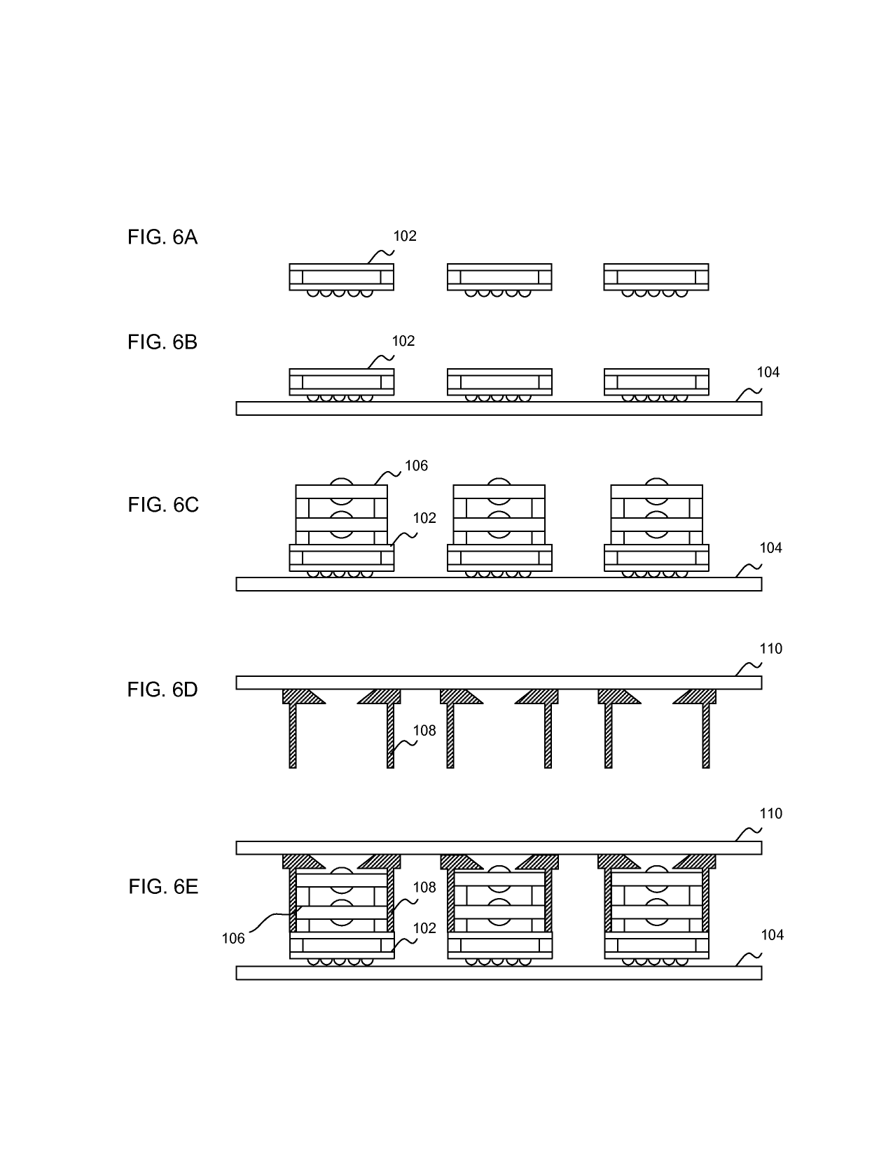

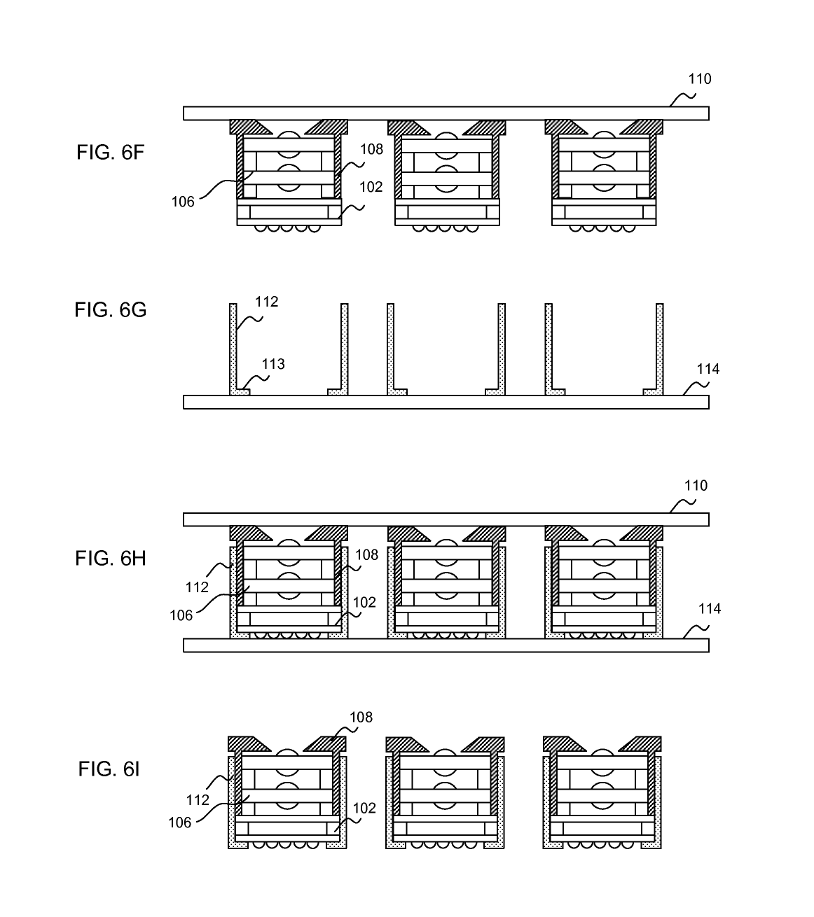

In an assembly process of one example, each component, including the lens stack, the image sensor module, the protective tube, and the metal housing, may all be singulated and assembled individually as shown and described with respect to FIGS. 3A-3E for explanation purposes. In another example, the components may be assembled in wafer level as shown in the example below with respect to FIGS. 6A-6I. It is appreciated that although FIGS. 6A-6I illustrate three units of wafer level camera modules for explanation purposes, there may be hundreds or thousands units on a wafer in accordance with the teachings of the present invention.

To illustrate, FIGS. 6A-6I show an example assembly process in wafer level using the reconstruction of components in wafer level after singulation, in accordance with the teachings of the present invention. FIG. 6A shows that image sensor modules 102 are singulated after they are fabricated in wafer level. FIG. 6B shows that the singulated image sensor modules 102 are reconstructed or rearranged back in wafer level by mounting them on a substrate or a tape 104. FIG. 6C shows that lens stacks 106 are singulated after they are fabricated in wafer level, and disposed on image sensor modules 102. Glue or an adhesive may be applied between lens stacks 106 and image sensor modules 102. FIG. 6D shows that the fabricated protective tubes 108 are reconstructed in wafer level by mounting them on a substrate or a tape 110. FIG. 6E shows protective tubes 108 disposed on image sensor modules 102. In one example, glue or an adhesive is applied between protective tubes 108 and image sensor modules 102. FIG. 6F shows substrate or tape 104 mounting image sensor modules 102 being removed. FIG. 6G shows that the fabricated metal housings 112 including housing feet 113 are reconstructed in wafer level by mounting them on a substrate or a tape 114. FIG. 6H shows metal housings enclosing protective tubes 108. Glue or an adhesive may be applied between the inner surface of housing feet 113 of metal housings 112 and image sensor modules 102. FIG. 6I shows substrate or tape 114 mounting metal housings 112 and substrate or tape 104 mounting protective tubes 108 being removed.

In various examples, some components may not necessarily be singulated in the order represented above by FIGS. 6A-6I for explanation purposes. For instance, in one example, image sensor modules 102 may not be singulated until the step shown in FIG. 6E. Other arrangements of singulation and reconstruction are possible, including the reconstruction of lens stacks 106 in wafer level in accordance with the teachings of the present invention.

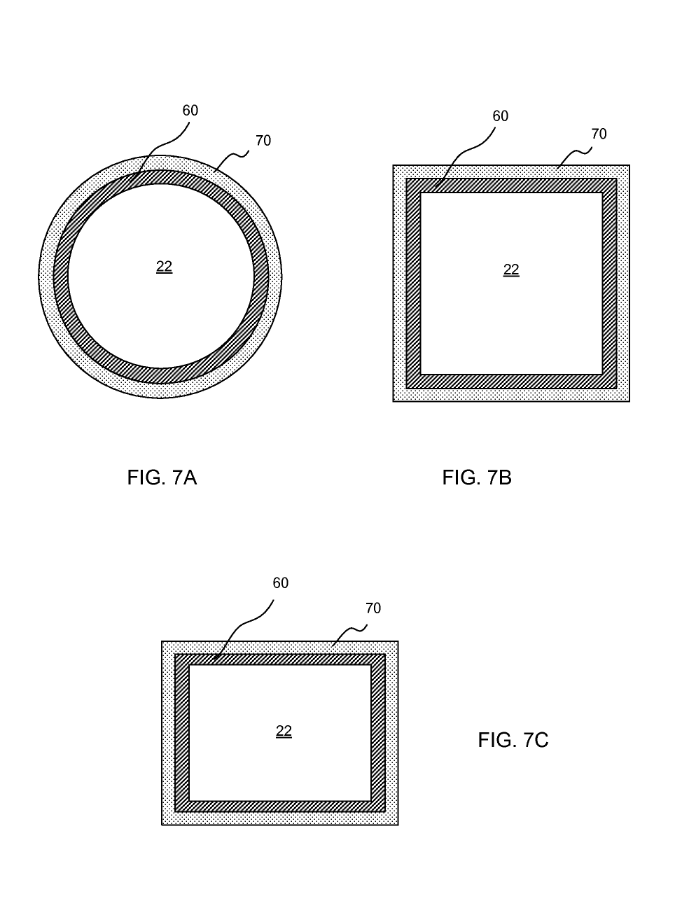

It is to be understood that the cross-section of lens stacks, protective tubes and metal housings illustrated in the above described figures can be circular, square, rectangular or other shapes. To illustrate, FIGS. 7A-7C are cross-section illustrations of various examples along line A-A′ of the example depicted in FIG. 3E. As shown, FIG. 7A illustrates a cross-section of lens stack 22, protective tube 60 and metal housing 70 having a circular shape. FIG. 7B illustrates a cross-section of lens stack 22, protective tube 60 and metal housing 70 having a square shape. FIG. 7C illustrates a cross-section of lens stack 22, protective tube 60 and metal housing 70 having a rectangular shape.

In the examples shown in the previous figures, there is no gap between lens stack 22 and the wall of protective tube 60. In other examples, it is appreciated that there may be a gap between lens stack 22 and the wall of protective tube 60 in accordance with the teachings of the present invention. In addition, in various examples, there is no gap between the wall of protective tube 60 and the wall of metal housing 70 as shown in the figures above. In other examples, there may be a gap between the wall of protective tube 60 and the wall of metal housing 70 (not shown) in accordance with the teachings of the present invention.

The above description of illustrated examples of the present invention, including what is described in the Abstract, are not intended to be exhaustive or to be limitation to the precise forms disclosed. While specific embodiments of, and examples for, the invention are described herein for illustrative purposes, various equivalent modifications are possible without departing from the broader spirit and scope of the present invention. Indeed, it is appreciated that the specific example voltages, currents, frequencies, power range values, times, etc., are provided for explanation purposes and that other values may also be employed in other embodiments and examples in accordance with the teachings of the present invention.

These modifications can be made to examples of the invention in light of the above detailed description. The terms used in the following claims should not be construed to limit the invention to the specific embodiments disclosed in the specification and the claims. Rather, the scope is to be determined entirely by the following claims, which are to be construed in accordance with established doctrines of claim interpretation. The present specification and figures are accordingly to be regarded as illustrative rather than restrictive.

What is claimed is:

1. An apparatus comprising:
an image sensor module;
a lens stack disposed on the image sensor module;
a protective tube disposed on the image sensor module and enclosing the lens stack; and
a metal housing enclosing the protective tube, the metal housing including a housing foot adapted to secure the image sensor module between the housing foot of the metal housing and the protective tube.

2. The apparatus of claim 1, wherein a first adhesive is applied between the lens stack and the image sensor module.

3. The apparatus of claim 1, wherein a second adhesive is applied between the housing foot and the image sensor module.

4. The apparatus of claim 1, wherein a third adhesive is applied between the protective tube and the image sensor module.

5. The apparatus of claim 1, wherein the image sensor module comprises an image sensor die, a spacer mounted on the image sensor die, a cover glass mounted on the spacer, and a plurality of solder balls mounted to the image sensor die.

6. The apparatus of claim 1, wherein the lens stack comprises at least one lens.

7. The apparatus of claim 1, wherein the protective tube includes a cap having a ledge.

8. The apparatus of claim 1, wherein the lens stack is in contact with an inner wall of the protective tube enclosing the lens stack.

9. The apparatus of claim 1, wherein the protective tube includes a thinned wall that defines a stop and a recess in the protective tube and are adapted to accept and hold the image sensor module.

10. The apparatus of claim 1, wherein a cross-section of the lens stack, the protective tube, and the metal housing is one of circular, square, and rectangular shapes.

11. A method for assembly comprising:
attaching a plurality of lens stacks onto a plurality of image sensor modules;
enclosing the plurality of lens stacks in a plurality of protective tubes;
enclosing the plurality of protective tubes in a plurality of metal housings, wherein each one of the metal housings includes a housing foot; and
securing the image sensor modules between the housing feet of the plurality of metal housings and the plurality of protective tubes.

12. The method of claim 11 wherein attaching the plurality of lens stacks onto the plurality of image sensor modules comprises applying a first adhesive between the plurality of lens stacks and the plurality of image sensor modules.

13. The method of claim 11 further comprising applying a second adhesive between the housing feet of the plurality of metal housings and the plurality of image sensor modules.

14. The method of claim 11 further comprising applying a third adhesive between the plurality of protective tubes and the plurality of image sensor modules.

15. The method of claim 11 further comprising singulating the plurality of image sensor modules after fabricating the plurality of image sensor modules in wafer level.

16. The method of claim 11 further comprising singulating the plurality of lens stacks after fabricating the plurality of lens stacks in wafer level.

17. The method of claim 11 further comprising mounting the plurality of protective tubes on a first tape to reconstruct the plurality of protective tubes in wafer level.

18. The method of claim 11 further comprising mounting the plurality of metal housings on a second tape to reconstruct the plurality of metal housings in wafer level.

19. A method for assembly comprising:
attaching a lens stack onto an image sensor module;
enclosing the lens stack in a protective tube;
enclosing the protective tube in a metal housing having a housing foot; and
securing the image sensor module between the housing foot of the metal housing and the protective tube.

20. The method of claim 19 wherein attaching the lens stack onto the image sensor module comprises applying a first adhesive between the lens stack and the image sensor module.

21. The method of claim 19 further comprising applying a second adhesive between the housing foot of the metal housing and the image sensor module.

22. The method of claim 19 further comprising applying a third adhesive between the protective tube and the image sensor module.
